(19) United States
(12) Patent Application Publication
(10) Pub. No.: US 2026/0271711 A1
(43) Pub. Date: Sep. 10, 2026

(54) HEAT TRANSFER STRUCTURES FOR SEMICONDUCTOR APPARATUSES

(71) Applicant: Micron Technology, Inc., Boise, ID (US)

(72) Inventors: Chenxi Li, Boise, ID (US); Michel Koopmans, Boise, ID (US); Amy Rae Griffin, Boise, ID (US)

(21) Appl. No.: 19/542,304

(22) Filed: Feb. 17, 2026

Related U.S. Application Data
(60) Provisional application No. 63/768,768, filed on Mar. 7, 2025.

(51) Int. Cl. H10W 40/20; H10B 80/00; H10D 80/30; H10W 20/41; H10W 20/47; H10W 20/48; H10W 40/00; H10W 40/25; H10W 90/00

(52) U.S. Cl. CPC H10W 40/233; H10B 80/00; H10D 80/30; H10W 20/435; H10W 20/47; H10W 20/48; H10W 40/03; H10W 40/254; H10W 40/258; H10W 90/792

(57) ABSTRACT

Methods, systems, and devices for heat transfer structures for semiconductor apparatuses are described. A semiconductor apparatus may include thermal vias within or between semiconductor components to increase an effective thermal conductivity and reduce an operating temperature of the system. The thermal vias may include materials, such as diamond-form carbon or aluminum nitride, with relatively high thermal conductivity and relatively low electrical conductivity, which may enable the thermal vias to contact and dissipate heat from the conductive lines without creating an electrical continuity. One or more thermal vias may be placed between conductive lines of a respective semiconductor component, between conductive lines and a substrate of a semiconductor component, or any combination thereof. Additionally, or alternatively, one or more thermal vias may be placed along a bonding interface between two or more semiconductor components.

### CROSS REFERENCE

The present Application for Patent claims priority to U.S. Patent Application No. 63/768,768 by Li et al., entitled “HEAT TRANSFER STRUCTURES FOR SEMICONDUCTOR APPARATUSES,” filed Mar. 07, 2025, which is assigned to the assignee hereof, and which is expressly incorporated by reference in its entirety herein.

### TECHNICAL FIELD

The following relates to one or more semiconductor systems, including heat transfer structures for semiconductor apparatuses.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells. In some examples, accessing information in a memory device may generate heat at various components of the memory device (e.g., at access lines of the memory device).

### BRIEF DESCRIPTION OF THE DRAWINGS

FIGS. 1 and 2 show examples of systems that supports heat transfer structures for semiconductor apparatuses in accordance with examples as disclosed herein.

FIG. 3–5 show examples of architectures that support heat transfer structures for semiconductor apparatuses in accordance with examples as disclosed herein.

FIGS. 6 and 7 show flowcharts illustrating methods that support heat transfer structures for semiconductor apparatuses in accordance with examples as disclosed herein.

### DETAILED DESCRIPTION

Some semiconductor systems (e.g., memory systems, processor systems, systems having a combination of memory and processing) may include a stack of semiconductor components (e.g., semiconductor dies), which may include one or more memory dies (e.g., memory dies, array dies, memory array dies) or one or more stacks of memory dies that are stacked with a logic die that is operable to access a set of memory arrays distributed across the one or more memory dies. Such a stacked architecture may be implemented as part of a high bandwidth memory (HBM) system or a 3D stacked memory system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Some semiconductor components in a semiconductor system (e.g., a semiconductor device, a semiconductor wafer, a semiconductor die, an HBM system, a 3D stacked memory system, or other stacked systems, a semiconductor apparatus) may include interconnection layers (e.g., front end of line (FEOL) layers, back end of line (BEOL) layers, layers including a dielectric material and conductive lines) that interconnect circuitry of the same semiconductor component, that connect the circuitry of the semiconductor component with another semiconductor component (e.g., in a semiconductor system having multiple semiconductor components), or both. For example, circuitry of a semiconductor component may be formed at least in part from a doped portion of a substrate (e.g., a front side of the substrate), and interconnection layers may include conductive traces that interconnect portions of such circuitry. In some cases, stacks of interconnection layers, or isolation layers therebetween, may increase thermal resistance of the semiconductor system, a heat generation of the system, or both. For example, a dielectric material within or between interconnection layers may be associated with a relatively low thermal conductivity, which may limit an overall thermal conductivity through a semiconductor component. These factors may combine to result in overheating at a semiconductor system, or limit an operational density of a semiconductor system, which may reduce operational capacity, integrity, and performance (e.g., impairing memory or processing components, or reducing a usability of the memory or processing components).

In accordance with aspects disclosed herein, a semiconductor system may include thermal vias within a semiconductor component or between semiconductor components to increase an effective thermal conductivity and reduce operating temperatures of the system. Thermal vias may include materials (e.g., diamond-form carbon, aluminum nitride) with relatively high thermal conductivity and relatively low electrical conductivity, which may enable the thermal vias to contact and dissipate heat from the conductive lines without creating an electrical continuity (e.g., without a conductive path, without an electrical short-circuit). In some implementations, thermal vias may be placed between conductive lines of a respective semiconductor component, between conductive lines and a substrate of a semiconductor component, or any combination thereof. Additionally, or alternatively, one or more thermal vias may be placed (e.g., extend through an interface) between conductive lines of a first semiconductor component and conductive lines of a second semiconductor component, between conductive lines of the first semiconductor component and a substrate of the second semiconductor component, between a substrate of the first semiconductor component and the substrate of the second semiconductor component, or any combination thereof.

In addition to applicability in memory systems as described herein, techniques for heat transfer structures for semiconductor apparatuses (e.g., semiconductor components) may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by including thermal vias in various layers of a semiconductor system, which may reduce an operating temperature of the semiconductor system and support higher device density and power density, among other benefits.

Features of the disclosure are illustrated and described in the context of systems and architectures. Features of the disclosure are further illustrated and described in the context of flowcharts.

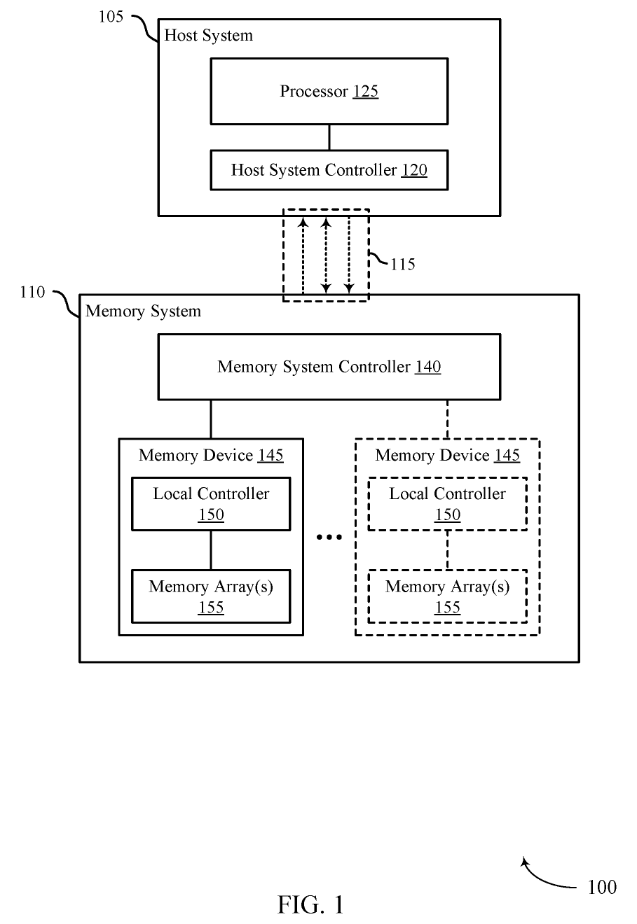

FIG. 1 shows an example of a system 100 that supports heat transfer structures for semiconductor apparatuses in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks, or in one or more other dies. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with one or more logic dies (e.g., that include aspects of the host system 105, that is coupled with another set of one or more dies that includes the host system 105) that includes interface blocks operable to access a set of memory arrays 155 distributed across the one or more second dies.

In accordance with aspects described herein, a semiconductor apparatus (e.g., a system 100, a memory system 110, a host system 105, a processor 125, a memory system controller 140, memory device(s) 145) may include thermal vias within or between semiconductor components (e.g., semiconductor wafers, semiconductor dies, reconstructed semiconductor dies or wafers) to increase an effective thermal conductivity and reduce an operating temperature of the semiconductor apparatus. The thermal vias may include materials (e.g., diamond-form carbon, aluminum nitride) with relatively high thermal conductivity and relatively low electrical conductivity, which may enable the thermal vias to contact and dissipate heat from components of the semiconductor apparatus without creating an electrical continuity. In some implementations, thermal vias may be placed between conductive lines (e.g., of a FEOL layer, of a BEOL layer, access lines) of a respective semiconductor component, between conductive lines and a substrate (e.g., a semiconductor substrate, a substrate of a crystalline semiconductor material) of a semiconductor component, or any combination thereof. Additionally, or alternatively, one or more thermal vias may be placed (e.g., extend through an interface) between conductive lines of a first semiconductor component and conductive lines of a second semiconductor component, between conductive lines of the first semiconductor component and a substrate of the second semiconductor component, between a substrate of the first semiconductor component and the substrate of the second semiconductor component, or any combination thereof.

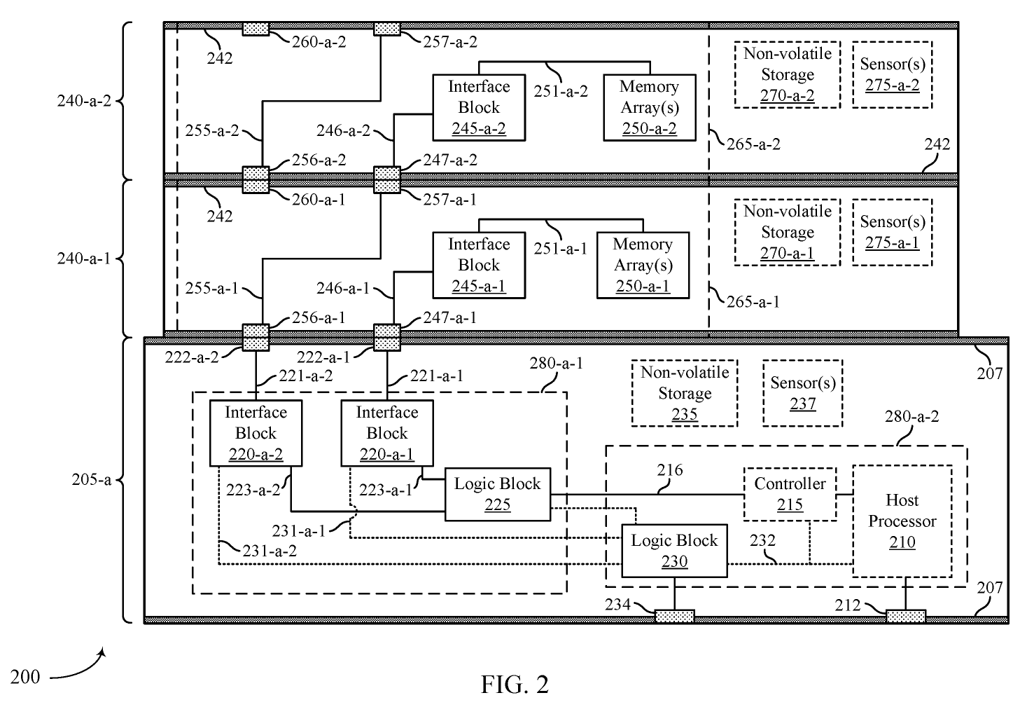

FIG. 2 shows an example of a system 200 (e.g., a semiconductor system, a system of coupled semiconductor dies, an HBM system, a 3D stacked memory system) that supports heat transfer structures for semiconductor apparatuses in accordance with examples as disclosed herein. The system 200 illustrates an example of a die 205 (e.g., a die 205-a, a semiconductor die, a logic die, a processor die, a host die, a logic unit, a semiconductor component) that is coupled with one or more dies 240 (e.g., dies 240-a-1 and 240-a-2, semiconductor dies, semiconductor components, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a 3D stacked memory configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

In accordance with aspects disclosed herein, a system 200 may include thermal vias within or between dies 205 or dies 240 to increase an effective thermal conductivity and reduce an operating temperature of the system 200. The thermal vias may include materials (e.g., diamond-form carbon, aluminum nitride) with relatively high thermal conductivity and relatively low electrical conductivity, which may enable the thermal vias to contact and dissipate heat from the conductive lines without creating an electrical continuity. One or more thermal vias may be placed between conductive lines of a respective die 205 or a die 240, between conductive lines and a substrate of a die 205 or die 240, or any combination thereof. Additionally, or alternatively, one or more thermal vias may be placed (e.g., extend through an interface) between conductive lines of the die 240-a-1 and conductive lines of the die 240-a-2 and/or conductive lines of the die 205-a, between conductive lines of the die 240-a-1 and a substrate of the die 240-a-2 and/or a substrate of the die 205-a, between a substrate of the die 240-a-1 and the substrate of the die 240-a-2 and/or the substrate of the die 205-a, or any combination thereof, among other implementations.

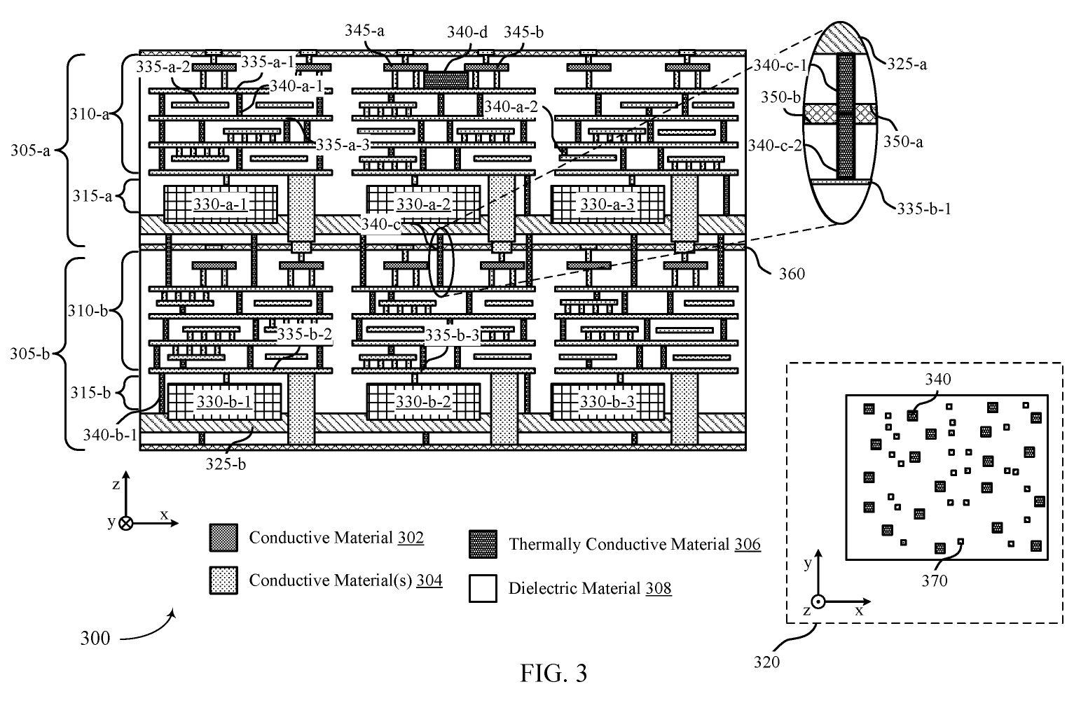

FIG. 3 shows an example of an architecture 300 (e.g., a material layout, a layout of a semiconductor system) that supports heat transfer structures for semiconductor apparatuses in accordance with examples as disclosed herein. The architecture 300 includes components 305 (e.g., components 305-a and 305-b, semiconductor components) that are bonded along an interface 360 (e.g., a bonding interface). Aspects of the architecture 300 may be described with reference to an x-direction, a y-direction, and a z-direction of the illustrated coordinate system, with FIG. 3 providing a view in an xz-plane, as well as a planar view 320 in an xy-plane. In some implementations, the z-direction may be a thickness direction of the components 305 or a stacking direction, and the interface 360 may be associated with respective surfaces 350 (e.g., bonding surfaces) of the components 305 in xy-planes.

Each of the components 305 may be an example of a semiconductor component, and may include one or more substrates 325 (e.g., a semiconductor substrate, a crystalline substrate) and circuitry 330. A substrate 325 may be a substrate of crystalline semiconductor material, such as silicon, germanium, silicon-germanium, gallium arsenide, gallium nitride, or other semiconductor materials. In some examples, a substrate 325 may include an SOI substrate (e.g., SOG, SOS), or epitaxial semiconductor materials formed on another substrate, among other examples.

Each of the components 305 may be an example of a respective type of semiconductor component. For example, each of the components 305 may be a semiconductor wafer (e.g., including a single substrate 325, before singulation into dies), a stack of semiconductor wafers (e.g., including multiple substrates 325), a semiconductor die (e.g., including a single substrate 325, after singulation from a wafer), a stack of semiconductor dies (e.g., including multiple substrates), or a reconstructed semiconductor wafer or die (e.g., including a set of multiple chiplets), among other examples. In some examples, the component 305-a may be a set of one or more semiconductor wafers and the component 305-b may be a semiconductor die (e.g., illustrative of a chip-to-wafer bonding arrangement) or a stack of semiconductor dies (e.g., illustrative of a stack-to-wafer bonding arrangement). In some other examples, the component 305-b may be a set of one or more semiconductor wafers and the component 305-a may be a semiconductor die or a stack of semiconductor dies. In some other examples, the component 305-a may be a set of one or more semiconductor dies and the component 305-b may be another set of one or more semiconductor dies (e.g., illustrative of a die-to-die, stack-to-die, or stack-to-stack bonding arrangement). In some other examples, the component 305-a may be a set of one or more semiconductor wafers and the component 305-b may be another set of one or more semiconductor wafers (e.g., illustrative of a wafer-to-wafer bonding arrangement, before singulation).

Circuitry 330 may include various circuit elements such as transistors, capacitors, resistors, inductors, and other circuit elements (e.g., operable circuit elements, processing circuitry, access circuitry, signaling circuitry). Circuitry 330, such as transistors and other semiconductor components of the circuitry 330, may be formed at least in part from a doped portion of a substrate 325 (e.g., one or more p-doped portions, one or more n-doped portions, or a combination thereof). A component 305 may also include one or more memory arrays (e.g., memory arrays 155, memory arrays 250), which may be included in circuitry 330 or coupled with circuitry 330, and at least a portion of the circuitry 330 may, in some examples, be configured for accessing the one or more memory arrays. For example, the component 305-a may include circuitry 330-a-1 through circuitry 330-a-3, and the component 305-b may include circuitry 330-b-1 through circuitry 330-b-3 that is coupled with (e.g., electrically) the circuitry 330-a-1 through 330-a-3, respectively, via any quantity of one or more conductive paths through the interface 360.

A component 305 may include interconnection layers and dielectric layers (e.g., adjacent dielectric layers, dielectric layers between an interconnection layer and a substrate 325 and circuitry 330, dielectric layers between interconnection layers). In some examples, at least a portion of the interconnection layers and dielectric layers of a component 305 may be referred to as BEOL circuitry 310, which may be formed after (e.g., over) FEOL circuitry 315. In some examples, FEOL circuitry 315 (e.g., FEOL circuitry 315-a and FEOL circuitry 315-b) may include the circuitry 330. Interconnection layers in the BEOL circuitry 310 and the FEOL circuitry 315 may each include conductive lines 335 (e.g., conductive traces, routing traces, interconnection lines, access lines) that extend along one or more directions in the respective interconnection layer (e.g., one or more directions in an xy-plane). For example, BEOL circuitry 310-a and BEOL circuitry 310-b may include one or more conductive lines 335-a and one or more conductive lines 335-b, respectively, that extend at least partially in an x-direction, a y-direction, or both. In some examples, the conductive lines 335 may be coupled with one or more contacts 345 (e.g., aluminum pads, contacts 256, 257, or 260). In some examples, the one or more contacts 345 may include one or more conductive materials 302 (e.g., metals, alloys, with or without a barrier material or conductive liner). It is to be understood that a component 305 in accordance with the described techniques may include any quantity of interconnection layers, which may each include various implementations of conductive lines 335 along one or more directions in an xy-plane within the respective interconnection layer. Each of the conductive lines 335 may include one or more conductive materials 304 (e.g., metals, alloys, with or without a barrier material or conductive liner), such as copper, tungsten, gold, silver, and other conductive materials.

Dielectric layers within BEOL circuitry 310 and the FEOL circuitry 315 may each include a dielectric material 308 that provides a degree of electrical isolation between adjacent layers or components. For example, the dielectric material 308 may be between at least some conductive lines 335 of different interconnection layers (e.g., between conductive lines 335-a-1 and 335-a-2, between conductive line 335-b-2 and substrate 325-b), between at least some conductive lines 335 and circuitry 330, or both. In some examples, the dielectric material 308 may include an oxide of silicon (e.g., silicon dioxide), or other insulating materials.

The planar view 320 illustrates a top-down view (e.g., a view of an xy-plane, a view along the z-direction) of a component 305 in a respective layer (e.g., isolation layer, between interconnection layers) of BEOL circuitry 310. In some examples, a layer may include one or more conductive vias 370. A conductive via 370 may provide a connection (e.g., an electrical connection) between one or more conductive lines 335 of the interconnection layers. For example, one or more first conductive lines 335 in a first interconnection layer may be coupled with one or more second conductive lines 335 in a second interconnection layer through one or more conductive vias 370 (e.g., the one or more conductive vias 370 may be in contact with the one or more first conductive lines 335 and the one or more second conductive lines 335). In some systems, a density of the conductive vias 370 through an xy-plane (e.g., along the z-direction) relative to the dielectric material 308 may be relatively small. For example, the conductive vias 370 may use less than 1–2% of the total material (including the dielectric material 308) in a respective isolation layer of BEOL circuitry 310.

In some examples, the dielectric material 308 may have a relatively high thermal resistance (e.g., a relatively low thermal conductivity), which may limit an overall thermal conductivity through a component 305 (e.g., along the z-direction) and be associated with relatively high internal temperatures of the component 305. For example, a relatively high thermal resistance of the dielectric material 308 may impede dissipation of heat generated by operations of the circuitry 330 or interconnection circuitry (e.g., conductive lines 335), including such heat generated by circuit elements of the same component 305, heat generated by circuit elements of one or more adjacent (e.g., stacked, coupled) components, such as the component 305-b, or a combination thereof.

Insufficient heat transfer and dissipation may degrade the conductive lines 335 (e.g., copper line, copper TSVs, or thermo-compression bonding (TCB) solder joints), or other features (e.g., of circuitry 330, of FEOL circuitry 315-b, of BEOL circuitry 310-b). For example, heat accumulation at the conductive lines 335 may melt the conductive lines 335, cause material migration, degrade dielectric isolation, or otherwise shorten functional lifespans (e.g., thermal migration of the conductive materials 304 in the conductive lines 335 may induce in-line void formation or short-circuiting during current flow). Further, insufficient thermal dissipation may increase heat accumulation in other layers of the component 305 (e.g., FEOL circuitry 315, circuitry 330), which may degrade a performance of the component 305 (e.g., based on increasing resistance of the component 305). At a package-level (e.g., in heterogeneous integration), a relatively hot component may increase the temperature of adjacent components (e.g., adjacent dies), thereby degrading overall package performance. Thus, it may be desirable to dissipate heat to avoid these and other issues.

As seen in the planar view 320, space of BEOL circuitry 310 (e.g., in an isolation layer) may be relatively unused (e.g., 1–2% of the BEOL circuitry 310 may include conductive vias 370). In some systems, additional conductive vias 370 may be introduced into the BEOL circuitry 310 to support excess heat transfer or dissipation from the conductive lines 335. However, application of additional conductive vias 370 to dissipate heat may be limited due to their implementation for certain electrical connections within the BEOL circuitry 310 (e.g., additional conductive vias 370 may unduly complicate the design of the BEOL circuitry 310 or introduce electrical shorts between interconnection layers).

In accordance with the examples disclosed herein, a component 305 may be configured with thermal vias 340 that include materials 306 with a relatively high thermal conductivity and a relatively low electrical conductivity (e.g., electrically insulating, configured for electrical isolation, configured without providing a conductive path), which may increase a degree of thermal conductivity through at least a portion of the BEOL circuitry 310, FEOL circuitry 315, or at the interface 360 between the components 305-a and 305-b, or a combination thereof. For example, the thermal vias 340 may include a dielectric material or a high bandgap semiconducting material (e.g., having an energy difference between the top of the valence band and the bottom of the conduction band of the material 306 may be relatively high, such as greater than 2 eV) with a relatively high thermal conductivity. The electrically insulating material properties of the thermal vias 340 (e.g., of the materials 306) may enable the thermal vias 340 to be in contact with (e.g., vertically connect) metal layers and components 305 and support thermal dissipation (e.g., along the z-direction).

One or more thermal vias 340 may be placed in contact with the conductive lines 335, the substrates 325-a and 325-b, the circuitry 330, or any combination thereof. For example, a thermal via 340-a-1 may be in contact (e.g., coupled) with the conductive line 335-a-1 and with the conductive line 335-a-3 (e.g., of respective interconnection layers), but the conductive lines 335-a-1 and 335-a-3 may not be electrically connected with each other (e.g., not operatively connected, without a signal carrying connection) based on the electrically insulating material of the thermal via 340-a-1. In some cases, a thermal via 340 may extend (e.g., in a z-direction) across multiple interconnection layers. For example, the thermal via 340-a-1 may extend across an interconnection layer that includes the conductive line 335-a-2. In some other examples, a thermal via 340 may extend between vertically-adjacent conductive lines 335, such as the thermal via 340-a-2. In another example, the thermal via 340-b-1 may contact (e.g., be coupled with) the substrate 325-b and a conductive line 335-b-2.

Additionally, or alternatively, one or more thermal vias 340 may be formed in a manner (e.g., as a bar of the thermally conductive material 306) that, when viewed along the z-direction (e.g., along a direction from the substrate), overlaps with a respective set of multiple conductive lines (e.g., conductive lines 335, of an interconnection layer, in an xy-plane), contacts (e.g., contacts 345, in an xy-plane), or both. For example, a thermal via 340-d may be formed along at least one direction (e.g., along the x-direction, along the y-direction, or both) to extend for a multiple of the pitch of contacts 345, such that the thermal via 340-d may overlap with (e.g., be in contact with) the contacts 345-a and 345-b. In some cases, because the material 306 may act as an isolating (e.g., dielectric) material under the operating conditions of a component 305, the thermal via 340-d may not electrically couple the contacts 345-a and 345-b, but may increase a thermal conductivity between the contacts 345-a and 345-b, allowing heat to dissipate through the component 305-b. It is to be understood that one or more thermal vias 340 formed as a bar may extend (e.g., in the x-direction, in the y-direction, or both) along portions of any other layer of a component 305 (e.g., along one or more layers of BEOL circuitry 310, FEOL circuitry 315, overlapping with multiple conductive lines 335, contacts 345, or both, at a pitch that is less than a pitch of conductive lines 335, contacts 345, or both).

As a result of including the thermal vias 340, or both, a thermal conductivity through respective layers (e.g., dielectric layers, isolation layers, layers including the dielectric material 308) may be higher along paths (e.g., paths along the z-direction, at location in an xy-plane) through the thermal vias 340, which may provide a net increase in thermal conductivity through the components 305-a and 305-b (e.g., along the z-direction), or more-uniform temperature distribution in x-directions, y-directions, or both.

In some examples, the one or more thermal vias 340 may be formed in layers of the FEOL circuitry 315, the BEOL circuitry 310, or both. For example, a first layer (e.g., an interconnection layer, a metal layer, a layer of the FEOL circuitry 315 or BEOL circuitry 310) may be formed over the substrate 325. The first layer may include multiple first conductive lives 335 extending over the substrate 325. A second layer may be formed over the first layer, the second layer including the dielectric material 308 along with one or more portions of the high thermal conductivity material 306 (e.g., diamond-form carbon, aluminum nitride) and, in some examples, vias 370 through the dielectric material 308 along a direction (e.g., a z-direction) from the substrate 325. The material 306 may have a thermal conductivity greater than a thermal conductivity of the dielectric material 308.

In some examples, one or more cavities may be formed in the second layer (e.g., in the dielectric material 308) and the one or more portions of the material 306 may be formed in the cavities. For example, the diamond-form carbon may be formed in the second layer after forming at least the first layer. In some examples, the one or more cavities may be formed to expose one or more conductive vias 370, conductive lines 335, or any combination thereof, based on removing the dielectric material 308 or conductive material 304 from the second layer. Additionally, or alternatively, a stack of multiple portions of the material 306 may be formed through one or more layers along the z-direction (e.g., to form the thermal via 340-a-1). For example, one or more vias (e.g., thermal vias 340, conductive vias 370), contacts 345, or both, may be formed at a surface of a component 305 based on cavity formation and fill operations (e.g., in accordance with a single-damascene conductor formation, in accordance with a multi-damascene conductor formation, such as a dual-damascene or triple-damascene operation). In some examples, a third layer may be formed over the second layer, the third layer including the multiple second conductive lines 335 extending over the substrate 325.

In some examples, at least one of the one or more portions of the material 306 may be formed in contact with the substrate 325 and in contact with one or more of the multiple second conductive lines 335 (e.g., the thermal via 340-b-1). Additionally, or alternatively, at least one or more of the portions of the material 306 may be formed in contact with the multiple first conductive lines 335, the multiple second conductive lines 335, or both (e.g., thermal vias 340-a-1, 340-a-2). In some examples, the circuitry 330 may be formed based on doping a semiconductor portion of the substrate 325, the circuitry 330 coupled with the multiple first conductive lines 335, the multiple second conductive lines 335, or both.

Additionally, or alternatively, one or more thermal vias 340 may be placed between two or more components 305 along the interface 360. For example, a thermal via 340-c may be placed between the substrate 325-a and a conductive line 335-b-1 at the interface 360. In some other examples, one or more thermal vias 340 may be placed between the substrates 325-a and 325-b, or between conductive lines 335-a of the component 305-a and conductive lines 335-b of the component 305-b. In some examples, the thermal via 340-c may be formed in a layer through the interface 360 (e.g., in an xy-plane). Additionally, or alternatively, one or more thermal vias 340 may be placed on a front side of a component 305 (e.g., on the front side of a wafer or die, along the positive z-direction from a substrate 325), on a back side of a component 305 (e.g., on the back side of a wafer or die, along the negative z-direction from a substrate 325), or a combination thereof.

In some other examples, a first portion 340-c-1 of the thermal via 340-c may be formed in the component 305-a and a second portion 340-c-2 of the thermal via 340-c may be formed in the component 305-b. For example, the first portion 340-c-1 may be formed based on etching a cavity in the surface 350-a of the component 305-a (e.g., from the surface 350-a of the component 305-a to a surface of the substrate 325-a) and forming the first portion 340-c-1 in the cavity. The second portion 340-c-2 may be formed based on etching a cavity in the surface 350-b of the component 305-b (e.g., from the surface 350-b of the component 305-b to the conductive line 335-b-1) and forming the second portion 340-c-2 in the cavity. In some examples, a width of one or more thermal vias 340 along the interface 360 (e.g., a width of the cavities before forming the thermal vias 340-c-1 and 340-c-2) may be larger than a width of one or more thermal vias 340 between one or more conductive lines 335 (e.g., thermal via 340-a-1).

The first portion 340-c-1 may be fused with the second portion 340-c-2 (e.g., to bond the component 305-a with the component 305-b). In some examples, a planarization operation (e.g., a chemical mechanical planarization (CMP) operation) may planarize multiple materials, including the materials 304, 306, 308, or a combination thereof. For example, the planarization operation may be configured to planarize the material 306 in the first portion 340-c-1 at the surface 350-a of the component 305-a, the material 306 in the second portion 340-c-2 at the surface 250-b of the component 305-b, or both. In some cases, the planarization operation may planarize the first portion 340-c-1 and the second portion 340-c-2 before fusing each of the portions 340-c-1 and 340-c-2.

In some examples, the thermal vias 340 may include a diamond-form carbon material (e.g., the material 306 may include diamond-form carbon). Diamond-form carbon may support improved characteristics of the architecture 300. For example, diamond-form carbon may have a heat transfer coefficient of around 800-2200 W(m*K) (e.g., depending on a size of sp3 carbon grains in the diamond-from carbon), which may be orders of magnitude higher than other materials (e.g., silicon-based dielectric materials, such as silicon dioxide which may have a heat transfer coefficient around 0.1–0.2 W/(m*K)). Accordingly, diamond-form carbon may support relatively improved heat rejection by the architecture 300 (e.g., reduced thermal resistance along the z-direction, reduced hot spots at locations along an xy-plane). Diamond-form carbon may also have relatively strong electrical isolation (e.g., insulation, a high bandgap, such as 2.2–4.8 eV) characteristics compared to metal materials, which may enable the thermal vias 340 to contact the conductive lines 335 without electrically shorting the conductive lines 335 between interconnection layers.

Diamond-form carbon may be formed in accordance with one or more threshold temperature ranges (e.g., the diamond-form carbon material may be low-temperature growth diamond). For example, the diamond-form carbon may be formed below a threshold temperature (e.g., below 350° C), which may be compatible with (e.g., not damage) circuitry 330, FEOL circuitry 315, and BEOL circuitry 310. In some examples, the carbon grain size may be based on forming the thermal vias 340 in accordance with the one or more threshold temperature ranges. For example, the grain size of the diamond-form carbon may be up to 250 nm in width based on forming the diamond-form carbon below the threshold temperature. In some examples, low-temperature growth diamond may include a majority of sp3 carbon grains rather than sp2 carbon grains compared to other diamond-like carbon materials (e.g., which may have a majority of sp2 carbon grains). For example, the low-temperature growth diamond may include a substantially crystalline structure (e.g., the material 306 may include 90% or greater sp3 carbon grains). In some examples, diamond-like carbon materials may include a relatively amorphous structure with relatively small sp2 carbon grains compared to sp3 carbon grains of low-temperature growth diamond.

Additionally, or alternatively, the thermal vias 340 may include aluminum nitride (e.g., the material 306 may include aluminum nitride). Aluminum nitride may support improved heat dissipation of the architecture 300. For example, aluminum nitride may have a heat transfer coefficient of around 150 W/(m*K), which may be higher than other materials (e.g., silicon-based dielectric materials). Aluminum nitride may also have relatively strong electrical isolation characteristics, such as having a bandgap of around 6 eV, which may be comparable to, or greater than, other dielectric materials in a component 305 (e.g., the silicon-based dielectric materials, such as SiO₂ may have a bandgap around 1.7 eV). In some examples, aluminum nitride may be formed using a sputter and spray process. Thus, in accordance with these and other examples, aluminum nitride or diamond-form carbon included in the thermal vias 340 may have a relatively low electrical conductivity and a relatively high thermal conductivity, which may provide relatively improved thermal dissipation performance of a semiconductor apparatus with features in accordance with the architecture 300.

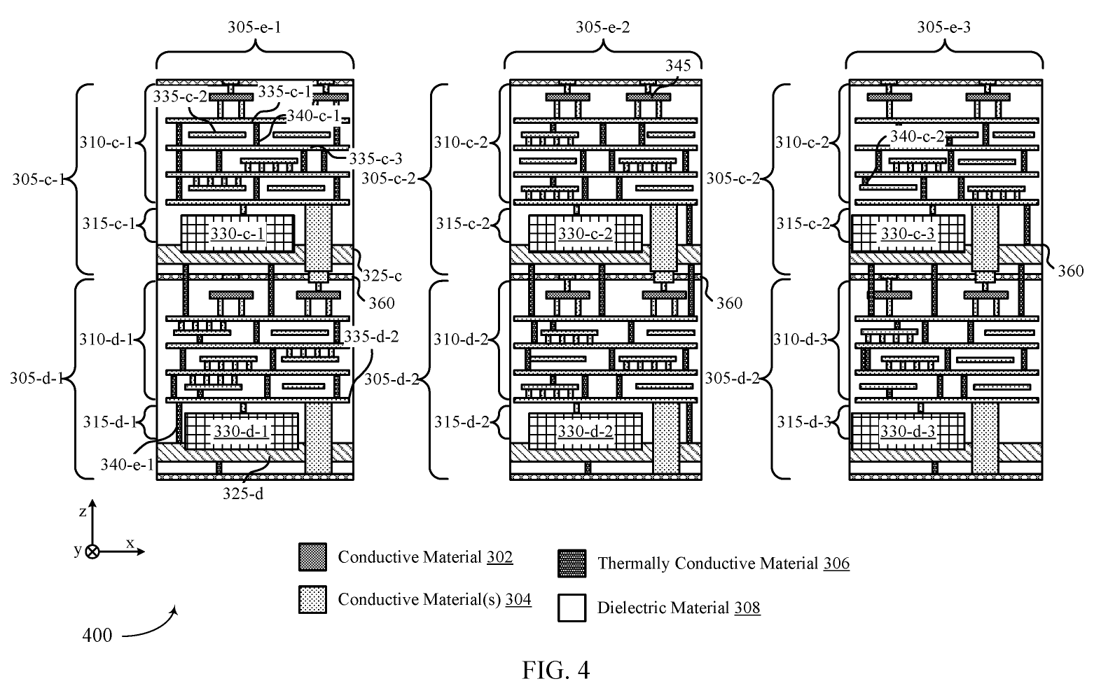

FIG. 4 shows an example of an architecture 400 (e.g., a material layout, a layout of a semiconductor system) that supports heat transfer structures for semiconductor apparatuses in accordance with examples as disclosed herein. In some examples, the architecture 400 may illustrate techniques implemented in accordance with a stacked die assembly (e.g., after singulation). For example, the architecture 400 includes components 305 (e.g., components 305-c and 305-d, semiconductor components, semiconductor dies) that are bonded along an interface 360 (e.g., a bonding interface) and singulated as components 305-e-1, 305-e-2, and 305-e-3 (e.g., stacked semiconductor dies, which may be singulated after stacking). Aspects of the architecture 400 may be described with reference to an x-direction, a y-direction, and a z-direction of the illustrated coordinate system, with FIG. 4 providing a view in an xz-plane. In some implementations, the z-direction may be a thickness direction of the components 305 or a stacking direction, and the interface 360 may be associated with respective surfaces 350 (e.g., bonding surfaces) of the components 305 in xy-planes.

Each of the components 305 may be an example of a respective type of semiconductor component as described herein. For example, each of the components 305 may be a semiconductor wafer, a stack of semiconductor wafers (e.g., including multiple substrates 325-c and 325-d), a semiconductor die (e.g., including a single substrate 325, after singulation from a wafer), a stack of semiconductor dies (e.g., including multiple substrates, including as components 305-e), or a reconstructed semiconductor wafer or die (e.g., including a set of multiple chiplets), among other examples. For example, the components 305-e-1 through 305-e-3 may be formed based on cutting through stacked semiconductor components 305 (e.g., stacked semiconductor wafers, based on performing a singulation process on the components 305-a and 305-b of architecture 300 described with reference to FIG. 3). In some other examples, a relatively larger component 305 (e.g., the component 305-a) may be cut one or more times to form the components 305-c-1, 305-c-2, and 305-c-3 and each of the components 305-c may be bonded with each of the components 305-d-1 through 305-d-3. Additionally, or alternatively, the components 305-c-1 through 305-c-3 may be stacked on a relatively larger component 305 (e.g., the component 305-b) before the component 305 is cut into the components 305-e-1 through 305-e-3. In some examples, the components 305-d may each be a portion of one or more semiconductor wafers and the components 305-c may each be a stack of semiconductor dies. In some other examples, each of the components 305-c may be a set of one or more semiconductor dies and each of the components 305-d may be another set of one or more semiconductor dies (e.g., illustrative of a die-to-die, stack-to-die, or stack-to-stack bonding arrangement). Each of the components 305-c, 305-d, and 305-e may include one or more respective substrates 325, circuitry 330, conductive lines 335, interconnection layers, dielectric layers, thermal vias 340, and contacts 345, as described with reference to FIG. 3.

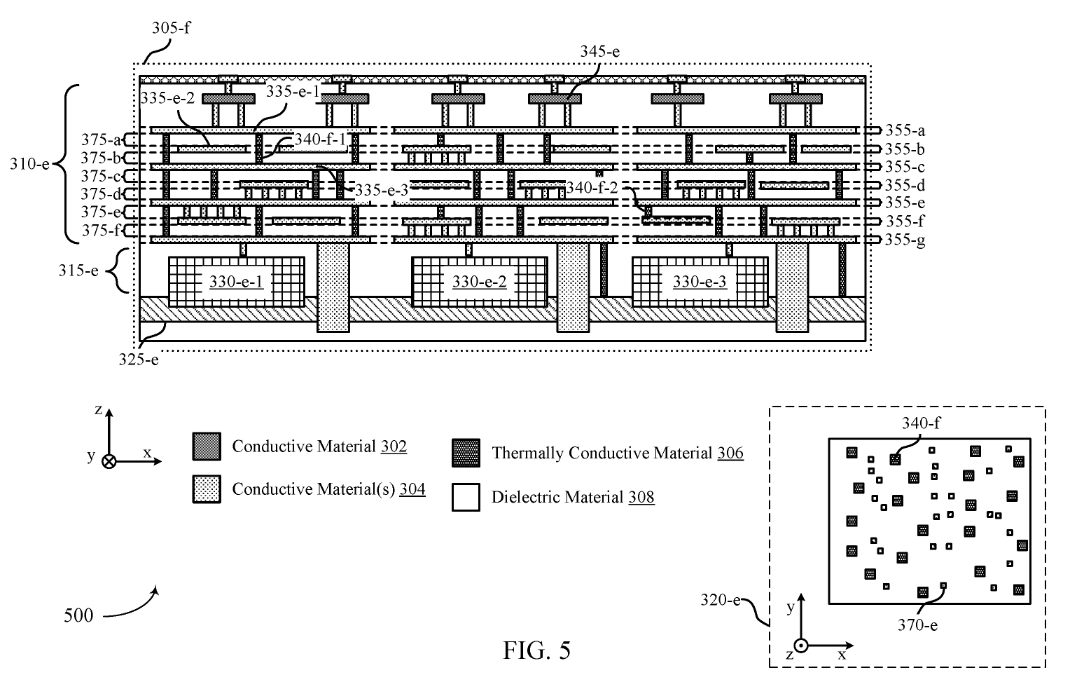

FIG. 5 shows an example of an architecture 500 (e.g., a material layout, a layout of a semiconductor system) that supports heat transfer structures for semiconductor apparatuses in accordance with examples as disclosed herein. In comparison to the stacked components 305 in the architecture 300, the architecture 500 illustrates the described techniques in the context of a single (e.g., unstacked) component 305-f (e.g., a single component 305 that implements aspects of one of a component 305-a or a component 305-b described with reference to FIG. 3) Aspects of the architecture 500 may be described with reference to an x-direction, a y-direction, and a z-direction of the illustrated coordinate system, with FIG. 5 providing a view in an xz-plane, as well as a planar view 320-e in an xy-plane. In some implementations, the z-direction may be a thickness direction of the component 305-f.

The component 305-f may include interconnection layers 355 and dielectric layers 375 (e.g., adjacent dielectric layers 375, dielectric layers 375 between an interconnection layer and a substrate 325-e and circuitry 330, dielectric layers between interconnection layers). In some examples, at least a portion of the interconnection layers and dielectric layers of a component 305-f may be referred to as BEOL circuitry 310-e, which may be formed after (e.g., over) FEOL circuitry 315-e. In some examples, FEOL circuitry 315-e may include the circuitry 330. Interconnection layers in the BEOL circuitry 310-e and the FEOL circuitry 315-e may each include conductive lines 335-e (e.g., conductive traces, routing traces, interconnection lines, access lines) that extend along one or more directions in the respective interconnection layer (e.g., one or more directions in an xy-plane). For example, BEOL circuitry 310-e may include one or more conductive lines 335-e that extend at least partially in an x-direction, a y-direction, or both. One or more thermal vias 340-f may extend across one or more interconnection layers 355 (e.g., interconnection layers 355-a, 355-b, 355-c, 355-d, 355-e,355-f, and 355-g), one or more dielectric layers 375 (e.g., dielectric layers 375-a, 375-b, 375-c, 375-d, 375-e, and 375-f), or a combination thereof (e.g., as front side thermal vias 340-f, as back side thermal vias 340-f, or a combination thereof). For example, a thermal via 340-f-1 may be in contact (e.g., coupled) with the conductive line 335-e-1 and with the conductive line 335-e-3 (e.g., of respective interconnection layers 355-e-1 and 355-e-3). In some cases, a thermal via 340 may extend (e.g., in a z-direction) across multiple interconnection layers 355. For example, the thermal via 340-f-1 may extend across interconnection layer 355-e-2. In some other examples, a thermal via 340 may extend between vertically-adjacent conductive lines 335, such as the thermal via 340-f-2 (e.g., that extends between interconnection layer 355-e and interconnection layer 355-f). The component 305-f may include one or more contacts 345-e and conductive vias 370-e, as described with reference to FIG. 3.

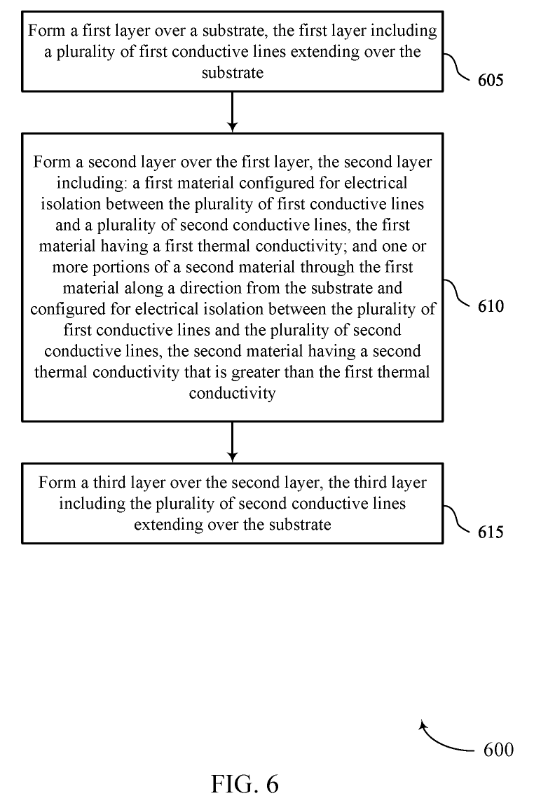

FIG. 6 shows a flowchart illustrating a method or methods 600 that supports heat transfer structures for semiconductor apparatuses in accordance with examples as disclosed herein. The operations of method 600 may be implemented by a manufacturing system or one or more controllers associated with a manufacturing system. For example, the operations of method 600 may be performed by a manufacturing system as described with reference to FIGS. 1 through 3. In some examples, a manufacturing system may execute a set of instructions to control the functional elements of the device to perform the described functions. Additionally, or alternatively, the manufacturing system may perform aspects of the described functions using special-purpose hardware.

At 605, the method 600 may include forming a first layer over a substrate (e.g., a substrate 325), the first layer including a plurality of first conductive lines (e.g., first conductive lines 335, of FEOL circuitry 315, of BEOL circuitry 310) extending over the substrate.

At 610, the method 600 may include forming a second layer over the first layer, the second layer including: a first material (e.g., dielectric material 308) configured for electrical isolation between the plurality of first conductive lines and a plurality of second conductive lines (e.g., second conductive lines 335, of FEOL circuitry 315, of BEOL circuitry 310), the first material having a first thermal conductivity; and one or more portions of a second material (e.g., material 306 of thermal vias 340) through the first material along a direction from the substrate and configured for electrical isolation between the plurality of first conductive lines and the plurality of second conductive lines, the second material having a second thermal conductivity that is greater than the first thermal conductivity.

At 615, the method 600 may include forming a third layer over the second layer, the third layer including the plurality of second conductive lines extending over the substrate.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method or apparatus including operations, features, circuitry, logic, means, or instructions, or any combination thereof for forming a first layer over a substrate (e.g., a first substrate 325), the first layer including a plurality of first conductive lines (conductive lines 335) extending over the substrate; forming a second layer over the first layer, the second layer including: a first material (e.g., the dielectric material 308) configured for electrical isolation between the plurality of first conductive lines and a plurality of second conductive lines, the first material having a first thermal conductivity; and one or more portions of a second material (e.g., the material 306 of the thermal vias 340) through the first material along a direction (e.g., a z-direction of the architecture 300) from the substrate and configured for electrical isolation between the plurality of first conductive lines and the plurality of second conductive lines, the second material having a second thermal conductivity that is greater than the first thermal conductivity; and forming a third layer over the second layer, the third layer including the plurality of second conductive lines extending over the substrate.

Aspect 2: The method or apparatus of aspect 1, where the second material includes diamond-form carbon.

Aspect 3: The method or apparatus of aspect 2, where forming the second layer includes operations, features, circuitry, logic, means, or instructions, or any combination thereof for forming the diamond-form carbon after forming at least the first layer.

Aspect 4: The method or apparatus of any of aspects 1 through 2, where the second material includes aluminum nitride.

Aspect 5: The method or apparatus of any of aspects 1 through 4, where at least one of the one or more portions of the second material is formed in contact with the substrate and in contact with one or more of the plurality of second conductive lines.

Aspect 6: The method or apparatus of any of aspects 1 through 5, where at least one of the one or more portions of the second material is formed in contact with the plurality of first conductive lines, the plurality of second conductive lines, or both.

Aspect 7: The method or apparatus of any of aspects 1 through 6, further including operations, features, circuitry, logic, means, or instructions, or any combination thereof for forming circuitry (e.g., circuitry 330) based at least in part on doping a semiconductor portion of the substrate, the circuitry coupled with the plurality of first conductive lines, the plurality of second conductive lines, or both.

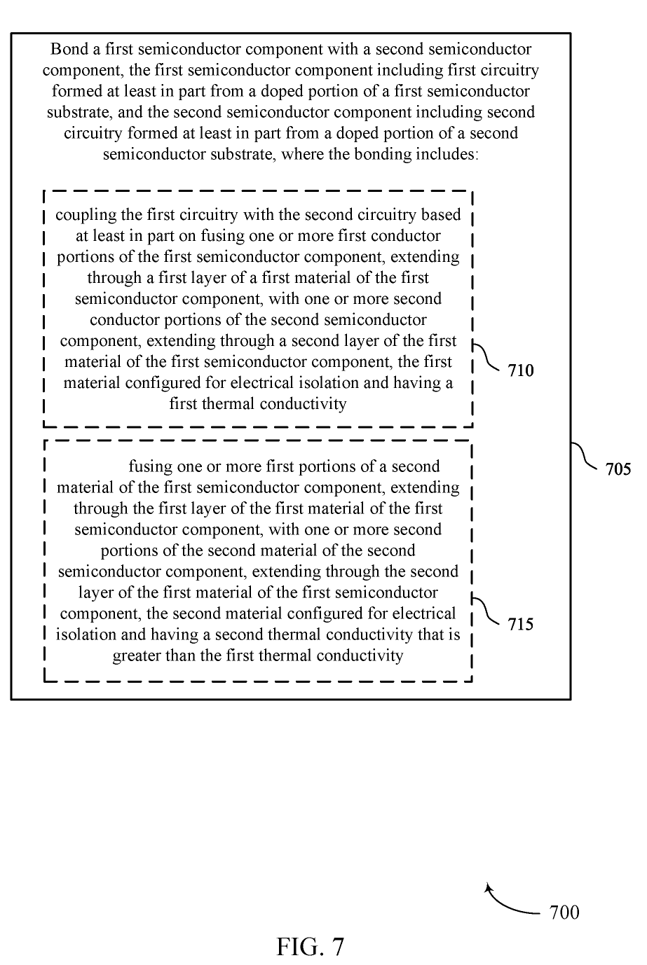

FIG. 7 shows a flowchart illustrating a method or methods 700 that supports heat transfer structures for semiconductor apparatuses in accordance with examples as disclosed herein. The operations of method 700 may be implemented by a manufacturing system or one or more controllers associated with a manufacturing system. For example, the operations of method 700 may be performed by a manufacturing system as described with reference to FIGS. 1 through 3. In some examples, a manufacturing system may execute a set of instructions to control the functional elements of the device to perform the described functions. Additionally, or alternatively, the manufacturing system may perform aspects of the described functions using special-purpose hardware.

At 705, the method 700 may include bonding a first semiconductor component (e.g., a first component 305) with a second semiconductor component (e.g., a second component 305), the first semiconductor component including first circuitry (e.g., first circuitry 330, first FEOL circuitry 315, first BEOL circuitry 310) formed at least in part from a doped portion of a first semiconductor substrate (e.g., a first substrate 325), and the second semiconductor component including second circuitry (e.g., second circuitry 330, second FEOL circuitry 315, second BEOL circuitry 310) formed at least in part from a doped portion of a second semiconductor substrate (e.g., a second substrate 325).

In some examples, at 710, the bonding may include coupling the first circuitry with the second circuitry based at least in part on fusing one or more first conductor portions of the first semiconductor component, extending through a first layer of a first material (e.g., dielectric material 308) of the first semiconductor component, with one or more second conductor portions of the second semiconductor component, extending through a second layer of the first material of the first semiconductor component, the first material configured for electrical isolation and having a first thermal conductivity.

In some examples, at 715 (e.g., concurrently with the operations of 710, during a duration different from the operations of 710), the bonding may include fusing one or more first portions of a second material (e.g., material 306) of the first semiconductor component, extending through the first layer of the first material of the first semiconductor component, with one or more second portions of the second material of the second semiconductor component, extending through the second layer of the first material of the first semiconductor component (e.g., forming the thermal via 340-c), the second material configured for electrical isolation and having a second thermal conductivity that is greater than the first thermal conductivity.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 8: A method or apparatus including operations, features, circuitry, logic, means, or instructions, or any combination thereof for bonding a first semiconductor component (e.g., a first component 305) with a second semiconductor component (e.g., a second component 305), the first semiconductor component including first circuitry (e.g., first circuitry 330, first FEOL circuitry 315, first BEOL circuitry 310) formed at least in part from a doped portion of a first semiconductor substrate (e.g., a first substrate 325), and the second semiconductor component including second circuitry (e.g., second circuitry 330, second FEOL circuitry 315, second BEOL circuitry 310) formed at least in part from a doped portion of a second semiconductor substrate, where the bonding includes: coupling the first circuitry with the second circuitry based at least in part on fusing one or more first conductor portions of the first semiconductor component, extending through a first layer of a first material (e.g., dielectric material 308) of the first semiconductor component, with one or more second conductor portions of the second semiconductor component, extending through a second layer of the first material of the first semiconductor component, the first material configured for electrical isolation and having a first thermal conductivity; and fusing one or more first portions of a second material (e.g., material 306) of the first semiconductor component, extending through the first layer of the first material of the first semiconductor component, with one or more second portions of the second material of the second semiconductor component, extending through the second layer of the first material of the first semiconductor component, the second material configured for electrical isolation and having a second thermal conductivity that is greater than the first thermal conductivity.

Aspect 9: The method or apparatus of aspect 8, where at least one of the one or more first portions of the second material is in contact with the first semiconductor substrate, at least one of the one or more second portions of the second material is in contact with the second semiconductor substrate, or both.

Aspect 10: The method or apparatus of any of aspects 8 through 9, where at least one of the one or more first portions of the second material is in contact with one or more first conductors of the first semiconductor component, at least one of the one or more second portions of the second material is in contact with one or more second conductors of the second semiconductor component, or both.

Aspect 11: The method or apparatus of any of aspects 8 through 10, where the one or more first portions of the second material, the one or more second portions of the second material, or both are wider than the one or more first conductor portions and the one or more second conductor portions.

Aspect 12: The method or apparatus of any of aspects 8 through 11, where the second material includes diamond-form carbon.

Aspect 13: The method or apparatus of any of aspects 8 through 11, where the second material includes aluminum nitride.

It should be noted that the aspects described herein describe possible implementations, and that the operations and the steps may be rearranged or otherwise modified and that other implementations are possible. Further, portions from two or more of the methods may be combined.

An apparatus (e.g., a semiconductor apparatus) is described. The following provides an overview of aspects of the apparatus as described herein:

Aspect 14: A semiconductor apparatus, including: a substrate layer (e.g., including a substrate 325); a first layer over the substrate layer and including a plurality of first conductive lines (e.g., first conductive lines 335) extending over the substrate layer (e.g., along the x-direction, along the y-direction, or a combination thereof); a second layer over the substrate layer and including a plurality of second conductive lines (e.g., second conductive lines 335) extending over the substrate layer (e.g., along the x-direction, along the y-direction, or a combination thereof); and a third layer over the substrate layer and between the first layer and the second layer, the third layer including: a first material (e.g., dielectric material 308) configured for electrical isolation between the plurality of first conductive lines and the plurality of second conductive lines, the first material having a first thermal conductivity; and one or more portions of a second material (e.g., material of thermal vias 340) through the first material along a direction (e.g., the z-direction) from the substrate layer and configured for electrical isolation between the plurality of first conductive lines and the plurality of second conductive lines, the second material having a second thermal conductivity that is greater than the first thermal conductivity of the first material.

Aspect 15: The semiconductor apparatus of aspect 14, where at least one portion of the one or more portions of the second material is in contact with the substrate layer and in contact with one or more of the plurality of first conductive lines or one or more of the plurality of second conductive lines.

Aspect 16: The semiconductor apparatus of any of aspects 14 through 15, where at least one portion of the one or more portions of the second material is in contact with one or more of the plurality of first conductive lines, one or more of the plurality of second conductive lines, or both.

Aspect 17: The semiconductor apparatus of any of aspects 14 through 16, where the second material includes diamond-form carbon.

Aspect 18: The semiconductor apparatus of aspect 17, where the diamond-form carbon includes crystalline grains having a width between 100 nanometers and 250 nanometers.

Aspect 19: The semiconductor apparatus of any of aspects 14 through 18, where the second material includes aluminum nitride.

Aspect 20: The semiconductor apparatus of any of aspects 14 through 19, further including: circuitry (e.g., circuitry 330) formed from a doped semiconductor portion of the substrate layer, the circuitry coupled with the plurality of first conductive lines, the plurality of second conductive lines, or both.

An apparatus (e.g., a semiconductor apparatus) is described. The following provides an overview of aspects of the apparatus as described herein:

Aspect 21: A semiconductor apparatus, including: a first semiconductor substrate (e.g., a first substrate 325); a second semiconductor substrate (e.g., a second substrate 325); a layer of a first material (e.g., a material at an interface 360) configured for electrical isolation between the first semiconductor substrate and the second semiconductor substrate, the first material having a first thermal conductivity; and one or more portions of a second material (e.g., of thermal via(s) 340) through the layer of the first material and configured for electrical isolation, the second material having a second thermal conductivity that is greater than the first thermal conductivity.

Aspect 22: The semiconductor apparatus of aspect 21, where at least one of the one or more portions of the second material extends between the first semiconductor substrate and one or more of a plurality of conductive lines formed over the second semiconductor substrate.

Aspect 23: The semiconductor apparatus of aspect 22, further including: a third layer over the first semiconductor substrate, the third layer including a plurality of second conductive lines; and one or more second portions of the second material in contact with one or more of the plurality of conductive lines and one or more of the plurality of second conductive lines, where a width of the one or more portions of the second material is greater than a width of the one or more second portions of the second material.

Aspect 24: The semiconductor apparatus of any of aspects 21 through 23, where at least one of the one or more portions of the second material is in contact with the first semiconductor substrate, the second semiconductor substrate, or both.

Aspect 25: The semiconductor apparatus of any of aspects 21 through 24, further including: a bonding interface (e.g., the interface 360) between the first semiconductor substrate and the second semiconductor substrate, where at least one of the one or more portions of a second material includes portions of the second material that are fused at the bonding interface.

Aspect 26: The semiconductor apparatus of any of aspects 21 through 25, where the second material includes diamond-form carbon.

Aspect 27: The semiconductor apparatus of any of aspects 21 through 26, where the second material includes aluminum nitride.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor apparatus, comprising:
a substrate layer;
a first layer over the substrate layer and comprising a plurality of first conductive lines extending over the substrate layer;
a second layer over the substrate layer and comprising a plurality of second conductive lines extending over the substrate layer; and
a third layer over the substrate layer and between the first layer and the second layer, the third layer comprising:
a first material configured for electrical isolation between the plurality of first conductive lines and the plurality of second conductive lines, the first material having a first thermal conductivity; and
one or more portions of a second material through the first material along a direction from the substrate layer and configured for electrical isolation between the plurality of first conductive lines and the plurality of second conductive lines, the second material having a second thermal conductivity that is greater than the first thermal conductivity of the first material.

2. The semiconductor apparatus of claim 1, wherein at least one portion of the one or more portions of the second material is in contact with the substrate layer and in contact with one or more of the plurality of first conductive lines or one or more of the plurality of second conductive lines.

3. The semiconductor apparatus of claim 1, wherein at least one portion of the one or more portions of the second material is in contact with one or more of the plurality of first conductive lines, one or more of the plurality of second conductive lines, or both.

4. The semiconductor apparatus of claim 1, wherein the second material comprises diamond-form carbon.

5. The semiconductor apparatus of claim 4, wherein the diamond-form carbon comprises crystalline grains having a width between 100 nanometers and 250 nanometers.

6. The semiconductor apparatus of claim 1, wherein the second material comprises aluminum nitride.

7. The semiconductor apparatus of claim 1, further comprising:
circuitry formed from a doped semiconductor portion of the substrate layer, the circuitry coupled with the plurality of first conductive lines, the plurality of second conductive lines, or both.

8. A method, comprising:
forming a first layer over a substrate, the first layer comprising a plurality of first conductive lines extending over the substrate;
forming a second layer over the first layer, the second layer comprising:
a first material configured for electrical isolation between the plurality of first conductive lines and a plurality of second conductive lines, the first material having a first thermal conductivity; and
one or more portions of a second material through the first material along a direction from the substrate and configured for electrical isolation between the plurality of first conductive lines and the plurality of second conductive lines, the second material having a second thermal conductivity that is greater than the first thermal conductivity; and
forming a third layer over the second layer, the third layer comprising the plurality of second conductive lines extending over the substrate.

9. The method of claim 8, wherein the second material comprises diamond-form carbon.

10. The method of claim 9, wherein forming the second layer comprises:
forming the diamond-form carbon after forming at least the first layer.

11. The method of claim 8, wherein the second material comprises aluminum nitride.

12. The method of claim 8, wherein at least one of the one or more portions of the second material is formed in contact with the substrate and in contact with one or more of the plurality of second conductive lines.

13. The method of claim 8, wherein at least one of the one or more portions of the second material is formed in contact with the plurality of first conductive lines, the plurality of second conductive lines, or both.

14. The method of claim 8, further comprising:
forming circuitry based at least in part on doping a semiconductor portion of the substrate, the circuitry coupled with the plurality of first conductive lines, the plurality of second conductive lines, or both.

15. A semiconductor apparatus, comprising:
a first semiconductor substrate;
a second semiconductor substrate;
a layer of a first material configured for electrical isolation between the first semiconductor substrate and the second semiconductor substrate, the first material having a first thermal conductivity; and
one or more portions of a second material through the layer of the first material and configured for electrical isolation, the second material having a second thermal conductivity that is greater than the first thermal conductivity.

16. The semiconductor apparatus of claim 15, wherein at least one of the one or more portions of the second material extends between the first semiconductor substrate and one or more of a plurality of conductive lines formed over the second semiconductor substrate.

17. The semiconductor apparatus of claim 16, further comprising:
a third layer over the first semiconductor substrate, the third layer comprising a plurality of second conductive lines; and
one or more second portions of the second material in contact with one or more of the plurality of conductive lines and one or more of the plurality of second conductive lines, wherein a width of the one or more portions of the second material is greater than a width of the one or more second portions of the second material.

18. The semiconductor apparatus of claim 15, wherein at least one of the one or more portions of the second material is in contact with the first semiconductor substrate, the second semiconductor substrate, or both.

19. The semiconductor apparatus of claim 15, further comprising:
a bonding interface between the first semiconductor substrate and the second semiconductor substrate, wherein at least one of the one or more portions of the second material comprises portions of the second material that are fused at the bonding interface.

20. The semiconductor apparatus of claim 15, wherein the second material comprises diamond-form carbon.

21. The semiconductor apparatus of claim 15, wherein the second material comprises aluminum nitride.

22. A method of forming a semiconductor apparatus, comprising:
bonding a first semiconductor component with a second semiconductor component, the first semiconductor component comprising first circuitry formed at least in part from a doped portion of a first semiconductor substrate, and the second semiconductor component comprising second circuitry formed at least in part from a doped portion of a second semiconductor substrate, wherein the bonding comprises:
coupling the first circuitry with the second circuitry based at least in part on fusing one or more first conductor portions of the first semiconductor component, extending through a first layer of a first material of the first semiconductor component, with one or more second conductor portions of the second semiconductor component, extending through a second layer of the first material of the first semiconductor component, the first material configured for electrical isolation and having a first thermal conductivity; and
fusing one or more first portions of a second material of the first semiconductor component, extending through the first layer of the first material of the first semiconductor component, with one or more second portions of the second material of the second semiconductor component, extending through the second layer of the first material of the first semiconductor component, the second material configured for electrical isolation and having a second thermal conductivity that is greater than the first thermal conductivity.

23. The method of claim 22, wherein at least one of the one or more first portions of the second material is in contact with the first semiconductor substrate, at least one of the one or more second portions of the second material is in contact with the second semiconductor substrate, or both.

24. The method of claim 22, wherein at least one of the one or more first portions of the second material is in contact with one or more first conductors of the first semiconductor component, at least one of the one or more second portions of the second material is in contact with one or more second conductors of the second semiconductor component, or both.

25. The method of claim 22, wherein the one or more first portions of the second material, the one or more second portions of the second material, or both are wider than the one or more first conductor portions and the one or more second conductor portions.

26. The method of claim 22, wherein the second material comprises diamond-form carbon.

27. The method of claim 22, wherein the second material comprises aluminum nitride.

28. A semiconductor apparatus, formed by a process comprising:
forming a first layer over a substrate, the first layer comprising a plurality of first conductive lines extending over the substrate;
forming a second layer over the first layer, the second layer comprising:
a first material configured for electrical isolation between the plurality of first conductive lines and a plurality of second conductive lines, the first material having a first thermal conductivity; and
one or more portions of a second material through the first material along a direction from the substrate and configured for electrical isolation between the plurality of first conductive lines and the plurality of second conductive lines, the second material having a second thermal conductivity that is greater than the first thermal conductivity; and
forming a third layer over the second layer, the third layer comprising the plurality of second conductive lines extending over the substrate.

29. The semiconductor apparatus of claim 28, wherein the second material comprises diamond-form carbon or aluminum nitride.
